(19) United States
(12) Patent Application Publication
(10) Pub. No.: US 2025/0142191 A1
(43) Pub. Date: May 1, 2025

(54) REDUCED PRINTED CIRCUIT BOARD EXPANSION IN INTEGRATED SENSOR-LENS ASSEMBLIES

(71) Applicant: GoPro, Inc., San Mateo, CA (US)

(72) Inventor: Ian Copeland Griggs, San Francisco, CA (US)

(21) Appl. No.: 18/383,969

(22) Filed: Oct. 26, 2023

(51) Int. Cl. H04N 23/52; H04N 23/55; H04N 23/95; H05K 1/02; H05K 1/11; H05K 3/46

(52) U.S. Cl. CPC H04N 23/52; H04N 23/55; H04N 23/95; H05K 1/0298; H05K 1/115; H05K 3/4644; H05K 2201/068; H05K 2201/10151

(57) ABSTRACT

An integrated sensor-lens assembly (ISLA) for an image capture apparatus that defines an optical axis and includes: a lens holder; a cover glass holder that is connected to the lens holder, a printed circuit board (PCB) that is (directly or indirectly) connected to the cover glass holder within an optical tolerance loop of the ISLA; and an image sensor that is supported by the PCB. The ISLA is configured such that expansion of the PCB along the optical axis is constrained so as to maintain focus alignment of the ISLA.

### TECHNICAL FIELD

The present disclosure relates to integrated sensor-lens assemblies (ISLAs) in image capture apparatuses, and, more specifically, to reducing the expansion of one or more printed circuit boards (PCBs) included therein.

### BACKGROUND

Image capture apparatuses are used in a variety of applications (e.g., handheld cameras and video recorders, cell phones, drones, vehicles, etc.), and typically include: one or more lenses (or other such optical elements); one or more image sensors; and one or more PCBs that support the image sensor(s). The lens(es) capture content by receiving and focusing light, and the image sensor(s) convert the captured content into an electronic image signal that is processed by an image signal processor to generate an image In some image capture apparatuses, the lens(es) and the image sensor(s) are integrated into a single unit, which is known as an ISLA.

In order to produce high-quality, focused images, the lens(es) and the corresponding sensor(s) must be properly aligned in multiple degrees-of-freedom, as even small misalignments (e.g., in the position or the tilt of the lens(es) and/or the image sensor(s)) can negatively impact image quality. One of the factors affecting alignment and image quality is PCB expansion, which is often caused by fluctuations in temperature and/or humidity (e.g., moisture content). PCB expansion can create a variety of issues including, for example, alterations to the spacing between the lens(es) and the image sensor(s), component misalignment, and/or the movement of components out of acceptable manufacturing tolerances, each of which can result in a loss of optical focus alignment (e.g., focus shift), distortion (e.g., blurring), warpage, etc.

To address this concern, the present disclosure describes various structures, components, and methods that reduce (i.e., inhibit, if not entirely prevent) PCB expansion in ISLAs to maintain and improve focus alignment in an image capture apparatus.

### SUMMARY

In one aspect of the present disclosure, an ISLA for an image capture apparatus is disclosed. The ISLA includes: a lens holder; a cover glass holder that is connected to the lens holder; a PCB that is connected to the cover glass holder within an optical tolerance loop of the ISLA; and an image sensor that is connected to the PCB. The PCB includes at least one material having a coefficient of thermal expansion that lies substantially within the range of approximately 2 ppm/° C. to approximately 40 ppm/° C., and a coefficient of hygroscopic expansion that lies substantially within the range of approximately 2 ppm/100% Hu absorption to approximately 20 ppm/100% Hu absorption.

In certain embodiments, the PCB may be laminated in construction.

In certain embodiments, the PCB may include approximately 4 layers of substrate to approximately 8 layers of substrate.

In certain embodiments, each layer of substrate may define a generally equivalent thickness.

In certain embodiments, each layer of substrate may define a thickness that lies substantially within the range of approximately ½ mm to approximately 1 mm.

In certain embodiments, the PCB may include vias that are located within the optical tolerance loop, wherein the vias are configured to facilitate electrical and/or thermal communication between the layers of substrate.

In certain embodiments, each via may define a transverse cross-sectional dimension that lies substantially within the range of approximately 0.025 mm to approximately 0.5 mm.

In another aspect of the present disclosure, an ISLA for an image capture apparatus is disclosed. The ISLA defines an optical axis, and includes: a lens holder; a cover glass holder that is connected to the lens holder; a mounting plate that is connected to the cover glass holder; a base plate that is connected to the mounting plate via standoffs extending therebetween so as to define a receiving space; a PCB that is positioned within the receiving space such that the PCB is indirectly connected to the cover glass holder via the mounting plate, wherein the mounting plate and the base plate cooperate to constrain expansion of the PCB along the optical axis so as to maintain focus alignment of the ISLA; and an image sensor that is connected to the PCB.

In certain embodiments, the standoffs may extend through the PCB.

In certain embodiments, the PCB may be laminated in construction.

In certain embodiments, the PCB may include layers of substrate that are positioned in adjacent relation, and vias that are positioned within an optical tolerance loop of the ISLA, wherein the vias extend through the layers of substrate to facilitate electrical and/or thermal communication therebetween.

In certain embodiments, the vias may extend partially through the PCB.

In certain embodiments, the PCB may include first vias that extends inwardly from an exterior layer of substrate into intermediate layers of substrate, and second vias with opposite ends that are spaced inwardly from the exterior layer of substrate.

In another aspect of the present disclosure, a method of assembling an ISLA is disclosed. The method includes: connecting a lens holder to a cover glass holder; connecting an image sensor to a PCB; connecting the PCB to the cover glass holder; and constraining expansion of the PCB along an optical axis of the ISLA so as to maintain focus alignment of the ISLA.

In certain embodiments, connecting the PCB to the cover glass holder may include directly connecting the PCB to the cover glass holder.

In certain embodiments, constraining expansion of the PCB may include forming the PCB from at least one material having a coefficient of thermal expansion that lies substantially within the range of approximately 2 ppm/° C. to approximately 40 ppm/° C., and a coefficient of hygroscopic expansion that lies substantially within the range of approximately 2 ppm/100% Hu absorption to approximately 20 ppm/100% Hu absorption.

In certain embodiments, forming the PCB may include forming the PCB with a laminated construction that includes approximately 4 layers of substrate to approximately 8 layers of substrate.

In certain embodiments, forming the PCB may include forming the PCB such that each layer of substrate defines a generally equivalent thickness.

In certain embodiments, forming the PCB may include forming the PCB such that each layer of substrate defines a thickness that lies substantially within the range of approximately ½ mm to approximately 1 mm.

In certain embodiments, connecting the PCB to the cover glass holder may include indirectly connecting the PCB to the cover glass holder.

In certain embodiments, constraining expansion of the PCB may include interposing the PCB between a mounting plate and a base plate.

In certain embodiments, the method may further include connecting the mounting plate to the base plate via standoffs so as to define a receiving space that is configured to receive the PCB.

In certain embodiments, the method may further include connecting the mounting plate to the cover glass holder such that the mounting plate separates the PCB from the cover glass holder.

### BRIEF DESCRIPTION OF THE DRAWINGS

The present disclosure is best understood from the following detailed description when read in conjunction with the accompanying drawings. According to common practice, the various features of the drawings may not be to-scale, and the dimensions of the various features may be arbitrarily expanded or reduced. Additionally, in the interest of clarity, certain components, elements, and/or features may be omitted from certain drawings in the interest of clarity.

FIGS. 1A-1B are isometric views of an example of an image capture apparatus.

FIGS. 2A-2B are isometric views of another example of an image capture apparatus.

FIG. 3 is a top view of another example of an image capture apparatus.

FIG. 4 is a block diagram of electronic components of an image capture apparatus.

FIG. 5 is a partial, axial, cross-sectional view of an example of an ISLA according to one embodiment of the preset disclosure, which includes a lens assembly and a PCB subassembly.

FIG. 6 is a plan view of an example of a PCB included in the PCB subassembly seen in FIG. 5.

FIG. 7 is a partial, cross-sectional view of the PCB seen in FIG. 6.

FIG. 8 is an enlargement of the area of detail identified in FIG. 6.

FIG. 9 is a partial, cross-sectional view of an alternate embodiment of the PCB seen in FIG. 6.

FIG. 10 is a partial, perspective view of another example of an ISLA according to an alternate embodiment of the disclosure.

### DETAILED DESCRIPTION

The present disclosure describes an ISLA for an image capture apparatus. The ISLA defines an optical axis and includes: a lens holder; a cover glass holder that is connected to the lens holder; a PCB that is (directly or indirectly) connected to the cover glass holder within an optical tolerance loop of the ISLA; and an image sensor that is supported by the PCB. The ISLA is configured such that expansion of the PCB along the optical axis is constrained so as to maintain focus alignment of the ISLA.

For example, constraining expansion of the PCB may include forming the PCB from at least one material having a coefficient of thermal expansion that lies substantially within the range of approximately 2 ppm/° C. to approximately 40 ppm/° C., and a coefficient of hygroscopic expansion that lies substantially within the range of approximately 2 ppm/100% Hu absorption to approximately 20 ppm/100% Hu absorption. Additionally, or alternatively, constraining expansion of the PCB may include forming the PCB with a laminated construction that includes approximately 4 layers of substrate to approximately 8 layers of substrate and/or forming the PCB with an increased number of vias (compared to known PCBs and ISLAs) to mechanically lock together the layers of substrate.

Additionally, or alternatively, constraining expansion of the PCB may include interposing the PCB between a mounting plate and a base plate. The mounting plate and the base plate are connected (secured) via standoffs which define a receiving space that is configured to receive the PCB, and generally fixes the configuration of the receiving space, whereby the mounting plate and the base plate collectively constrain expansion of the PCB.

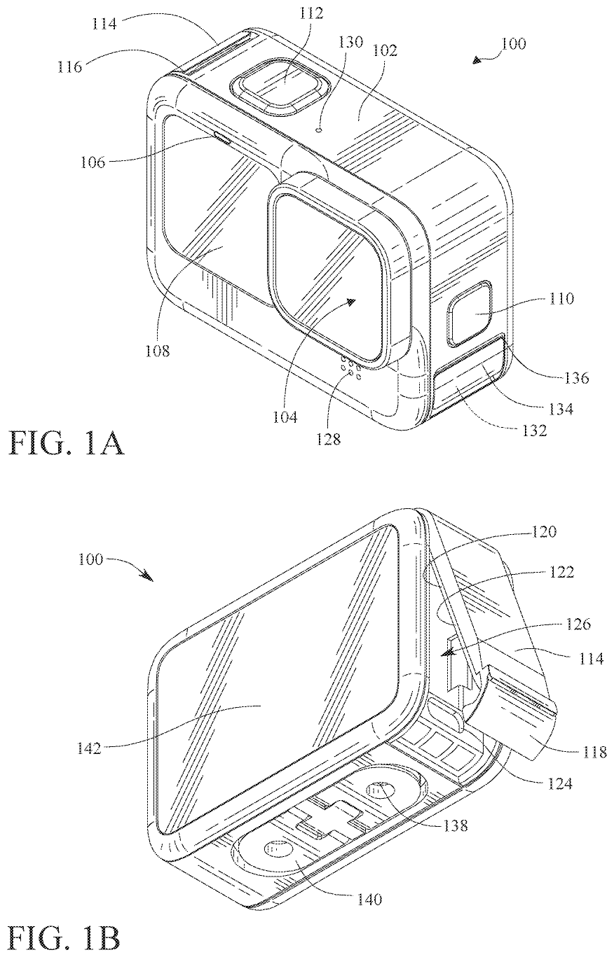

FIGS. 1A-1B are isometric views of an example of an image capture apparatus 100. The image capture apparatus 100 includes a body 102, an image capture device 104, an indicator 106, a display 108, a mode button 110, a shutter button 112, a door 114, a hinge mechanism 116, a latch mechanism 118, a seal 120, a battery interface 122, a data interface 124, a battery receptacle 126, microphones 128, 130, 132, a speaker 138, an interconnect mechanism 140, and a display 142. Although not expressly shown in FIGS. 1A-1B, the image capture apparatus 100 includes internal electronics, such as imaging electronics, power electronics, and the like, internal to the body 102 for capturing images and performing other functions of the image capture apparatus 100. The arrangement of the components of the image capture apparatus 100 shown in FIGS. 1A-1B is an example, other arrangements of elements may be used, except as is described herein or as is otherwise clear from context.

The body 102 of the image capture apparatus 100 may be made of a rigid material such as plastic, aluminum, steel, or fiberglass. Other materials may be used. The image capture device 104 is structured on a front surface of, and within, the body 102. The image capture device 104 includes a lens. The lens of the image capture device 104 receives light incident upon the lens of the image capture device 104 and directs the received light onto an image sensor of the image capture device 104 internal to the body 102. The image capture apparatus 100 may capture one or more images, such as a sequence of images, such as video. The image capture apparatus 100 may store the captured images and video for subsequent display, playback, or transfer to an external device. Although one image capture device 104 is shown in FIG. 1A, the image capture apparatus 100 may include multiple image capture devices, which may be structured on respective surfaces of the body 102.

As shown in FIG. 1A, the image capture apparatus 100 includes the indicator 106 structured on the front surface of the body 102. The indicator 106 may output, or emit, visible light, such as to indicate a status of the image capture apparatus 100. For example, the indicator 106 may be a light-emitting diode (LED). Although one indicator 106 is shown in FIG. 1A, the image capture apparatus 100 may include multiple indictors structured on respective surfaces of the body 102.

As shown in FIG. 1A, the image capture apparatus 100 includes the display 108 structured on the front surface of the body 102. The display 108 outputs, such as presents or displays, such as by emitting visible light, information, such as to show image information such as image previews, live video capture, or status information such as battery life, camera mode, elapsed time, and the like. In some implementations, the display 108 may be an interactive display, which may receive, detect, or capture input, such as user input representing user interaction with the image capture apparatus 100. In some implementations, the display 108 may be omitted or combined with another component of the image capture apparatus 100.

As shown in FIG. 1A, the image capture apparatus 100 includes the mode button 110 structured on a side surface of the body 102. Although described as a button, the mode button 110 may be another type of input device, such as a switch, a toggle, a slider, or a dial. Although one mode button 110 is shown in FIG. 1A, the image capture apparatus 100 may include multiple mode, or configuration, buttons structured on respective surfaces of the body 102. In some implementations, the mode button 110 may be omitted or combined with another component of the image capture apparatus 100. For example, the display 108 may be an interactive, such as touchscreen, display, and the mode button 110 may be physically omitted and functionally combined with the display 108.

As shown in FIG. 1A, the image capture apparatus 100 includes the shutter button 112 structured on a top surface of the body 102. The shutter button 112 may be another type of input device, such as a switch, a toggle, a slider, or a dial. The image capture apparatus 100 may include multiple shutter buttons structured on respective surfaces of the body 102. In some implementations, the shutter button 112 may be omitted or combined with another component of the image capture apparatus 100.

The mode button 110, the shutter button 112, or both, obtain input data, such as user input data in accordance with user interaction with the image capture apparatus 100. For example, the mode button 110, the shutter button 112, or both, may be used to turn the image capture apparatus 100 on and off, scroll through modes and settings, and select modes and change settings.

As shown in FIG. 1B, the image capture apparatus 100 includes the door 114 coupled to the body 102, such as using the hinge mechanism 116 (FIG. 1A). The door 114 may be connected (secured) to the body 102 using the latch mechanism 118 that releasably engages the body 102 at a position generally opposite the hinge mechanism 116. The door 114 includes the seal 120 and the battery interface 122. Although one door 114 is shown in FIG. 1A, the image capture apparatus 100 may include multiple doors respectively forming respective surfaces of the body 102, or portions thereof. The door 114 may be removable from the body 102 by releasing the latch mechanism 118 from the body 102 and decoupling the hinge mechanism 116 from the body 102.

In FIG. 1B, the door 114 is shown in a partially open position such that the data interface 124 is accessible for communicating with external devices and the battery receptacle 126 is accessible for placement or replacement of a battery. In FIG. 1A, the door 114 is shown in a closed position. In implementations in which the door 114 is in the closed position, the seal 120 engages a flange (not shown) to provide an environmental seal and the battery interface 122 engages the battery (not shown) to connect (secure) the battery in the battery receptacle 126.

As shown in FIG. 1B, the image capture apparatus 100 includes the battery receptacle 126 structured to form a portion of an interior surface of the body 102. The battery receptacle 126 includes operative connections for power transfer between the battery and the image capture apparatus 100. In some implementations, the battery receptacle 126 may be omitted. The image capture apparatus 100 may include multiple battery receptacles.

As shown in FIG. 1A, the image capture apparatus 100 includes a first microphone 128 structured on a front surface of the body 102, a second microphone 130 structured on a top surface of the body 102, and a third microphone 132 structured on a side surface of the body 102. The third microphone 132, which may be referred to as a drain microphone and is indicated as hidden in dotted line, is positioned (located) behind a drain cover 134, surrounded by a drain channel 136, and can drain liquid from audio components of the image capture apparatus 100. The image capture apparatus 100 may include other microphones on other surfaces of the body 102. The microphones 128, 130, 132 receive and record audio, such as in conjunction with capturing video or separate from capturing video. In some implementations, one or more of the microphones 128, 130, 132 may be omitted or combined with other components of the image capture apparatus 100.

As shown in FIG. 1B, the image capture apparatus 100 includes the speaker 138 structured on a bottom surface of the body 102. The speaker 138 outputs or presents audio, such as by playing back recorded audio or emitting sounds associated with notifications. The image capture apparatus 100 may include multiple speakers structured on respective surfaces of the body 102.

As shown in FIG. 1B, the image capture apparatus 100 includes the interconnect mechanism 140 structured on a bottom surface of the body 102. The interconnect mechanism 140 removably connects (secures) the image capture apparatus 100 to an external structure, such as a handle grip, another mount, or a securing device. The interconnect mechanism 140 includes folding protrusions configured to move between a nested or collapsed position as shown in FIG. 1B and an extended or open position. The folding protrusions of the interconnect mechanism 140 in the extended or open position may be coupled to reciprocal protrusions of other devices such as handle grips, mounts, clips, or like devices. The image capture apparatus 100 may include multiple interconnect mechanisms structured on, or forming a portion of, respective surfaces of the body 102. In some implementations, the interconnect mechanism 140 may be omitted.

As shown in FIG. 1B, the image capture apparatus 100 includes the display 142 structured on, and forming a portion of, a rear surface of the body 102. The display 142 outputs, such as presents or displays, such as by emitting visible light, data, such as to show image information such as image previews, live video capture, or status information such as battery life, camera mode, elapsed time, and the like. In some implementations, the display 142 may be an interactive display, which may receive, detect, or capture input, such as user input representing user interaction with the image capture apparatus 100. The image capture apparatus 100 may include multiple displays structured on respective surfaces of the body 102, such as the displays 108, 142 shown in FIGS. 1A-1B. In some implementations, the display 142 may be omitted or combined with another component of the image capture apparatus 100.

The image capture apparatus 100 may include features or components other than those described herein, such as other buttons or interface features. In some implementations, interchangeable lenses, cold shoes, and hot shoes, or a combination thereof, may be coupled to or combined with the image capture apparatus 100. For example, the image capture apparatus 100 may communicate with an external device, such as an external user interface device, via a wired or wireless computing communication link, such as via the data interface 124. The computing communication link may be a direct computing communication link or an indirect computing communication link, such as a link including another device or a network, such as the Internet. The image capture apparatus 100 may transmit images to the external device via the computing communication link.

The external device may store, process, display, or combination thereof, the images. The external user interface device may be a computing device, such as a smartphone, a tablet computer, a smart watch, a portable computer, personal computing device, or another device or combination of devices configured to receive user input, communicate information with the image capture apparatus 100 via the computing communication link, or receive user input and communicate information with the image capture apparatus 100 via the computing communication link. The external user interface device may implement or execute one or more applications to manage or control the image capture apparatus 100. For example, the external user interface device may include an application for controlling camera configuration, video acquisition, video display, or any other configurable or controllable aspect of the image capture apparatus 100. In some implementations, the external user interface device may generate and share, such as via a cloud-based or social media service, one or more images or video clips. In some implementations, the external user interface device may display unprocessed or minimally processed images or video captured by the image capture apparatus 100 contemporaneously with capturing the images or video by the image capture apparatus 100, such as for shot framing or live preview.

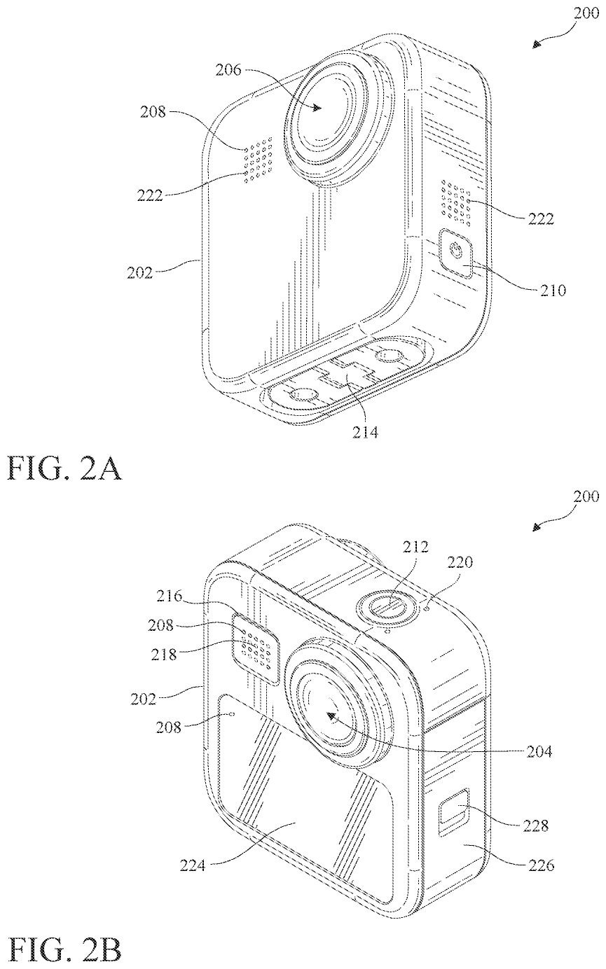

FIGS. 2A-2B illustrate another example of an image capture apparatus 200. The image capture apparatus 200 is similar to the image capture apparatus 100 shown in FIGS. 1A-1B. The image capture apparatus 200 includes a body 202, a first image capture device 204, a second image capture device 206, indicators 208, a mode button 210, a shutter button 212, an interconnect mechanism 214, a drainage channel 216, audio components 218, 220, 222, a display 224, and a door 226 including a release mechanism 228. The arrangement of the components of the image capture apparatus 200 shown in FIGS. 2A-2B is an example, other arrangements of elements may be used.

The body 202 of the image capture apparatus 200 may be similar to the body 102 shown in FIGS. 1A-1B. The first image capture device 204 is structured on a front surface of the body 202. The first image capture device 204 includes a first lens. The first image capture device 204 may be similar to the image capture device 104 shown in FIG. 1A. As shown in FIG. 2A, the image capture apparatus 200 includes the second image capture device 206 structured on a rear surface of the body 202. The second image capture device 206 includes a second lens. The second image capture device 206 may be similar to the image capture device 104 shown in FIG. 1A. The image capture devices 204, 206 are disposed on opposing surfaces of the body 202, for example, in a back-to-back configuration, Janus configuration, or offset Janus configuration. The image capture apparatus 200 may include other image capture devices structured on respective surfaces of the body 202.

As shown in FIG. 2B, the image capture apparatus 200 includes the indicators 208 associated with the audio component 218 and the display 224 on the front surface of the body 202. The indicators 208 may be similar to the indicator 106 shown in FIG. 1A. For example, one of the indicators 208 may indicate a status of the first image capture device 204 and another one of the indicators 208 may indicate a status of the second image capture device 206. Although two indicators 208 are shown in FIGS. 2A-2B, the image capture apparatus 200 may include other indictors structured on respective surfaces of the body 202.

As shown in FIGS. 2A-2B, the image capture apparatus 200 includes input mechanisms including the mode button 210, structured on a side surface of the body 202, and the shutter button 212, structured on a top surface of the body 202. The mode button 210 may be similar to the mode button 110 shown in FIG. 1B. The shutter button 212 may be similar to the shutter button 112 shown in FIG. 1A.

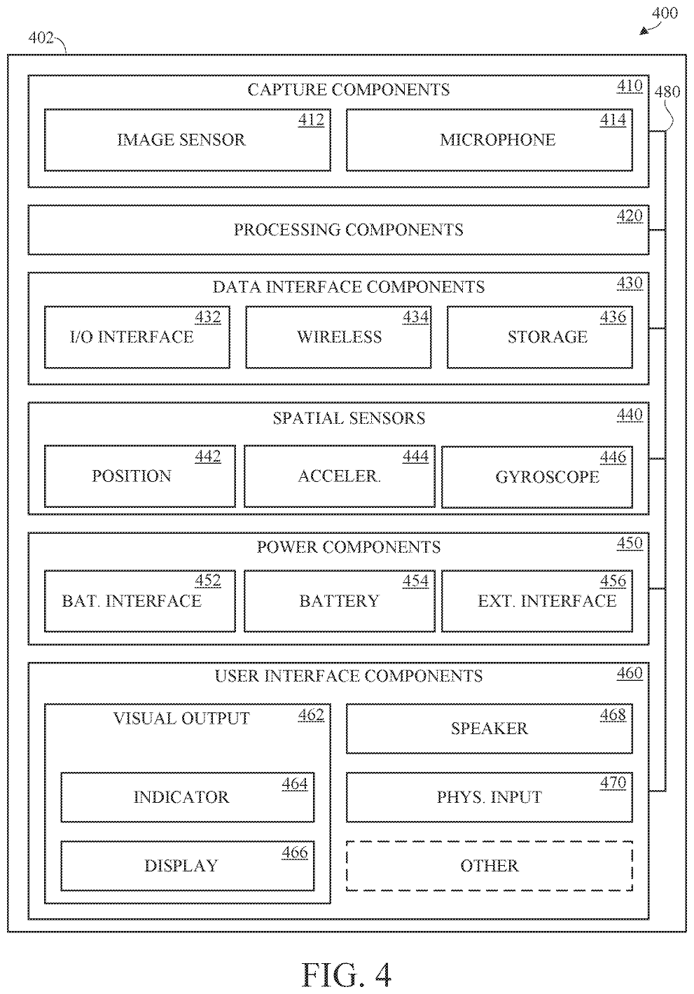

The image capture apparatus 200 includes internal electronics (not expressly shown), such as imaging electronics, power electronics, and the like, internal to the body 202 for capturing images and performing other functions of the image capture apparatus 200. An example showing internal electronics is shown in FIG. 4.

As shown in FIGS. 2A-2B, the image capture apparatus 200 includes the interconnect mechanism 214 structured on a bottom surface of the body 202. The interconnect mechanism 214 may be similar to the interconnect mechanism 140 shown in FIG. 1B.

As shown in FIG. 2B, the image capture apparatus 200 includes the drainage channel 216 for draining liquid from audio components of the image capture apparatus 200.

As shown in FIGS. 2A-2B, the image capture apparatus 200 includes the audio components 218, 220, 222, respectively structured on respective surfaces of the body 202. The audio components 218, 220, 222 may be similar to the microphones 128, 130, 132 and the speaker 138 shown in FIGS. 1A-1B. One or more of the audio components 218, 220, 222 may be, or may include, audio sensors, such as microphones, to receive and record audio signals, such as voice commands or other audio, in conjunction with capturing images or video. One or more of the audio components 218, 220, 222 may be, or may include, an audio presentation component that may present, or play, audio, such as to provide notifications or alerts.

As shown in FIGS. 2A-2B, a first audio component 218 is positioned (located) on a front surface of the body 202, a second audio component 220 is positioned (located) on a top surface of the body 202, and a third audio component 222 is positioned (located) on a back surface of the body 202. Other numbers and configurations for the audio components 218, 220, 222 may be used For example, the audio component 218 may be a drain microphone surrounded by the drainage channel 216 and adjacent to one of the indicators 208 as shown in FIG. 2B.

As shown in FIG. 2B, the image capture apparatus 200 includes the display 224 structured on a front surface of the body 202. The display 224 may be similar to the displays 108, 142 shown in FIGS. 1A-1B. The display 224 may include an I/O interface. The display 224 may include one or more of the indicators 208. The display 224 may receive touch inputs. The display 224 may display image information during video capture. The display 224 may provide status information to a user, such as status information indicating battery power level, memory card capacity, time elapsed for a recorded video, etc. The image capture apparatus 200 may include multiple displays structured on respective surfaces of the body 202. In some implementations, the display 224 may be omitted or combined with another component of the image capture apparatus 200.

As shown in FIG. 2B, the image capture apparatus 200 includes the door 226 structured on, or forming a portion of, the side surface of the body 202. The door 226 may be similar to the door 114 shown in FIG. 1A. For example, the door 226 shown in FIG. 2A includes a release mechanism 228 The release mechanism 228 may include a latch, a button, or other mechanism configured to receive a user input that allows the door 226 to change position. The release mechanism 228 may be used to open the door 226 for a user to access a battery, a battery receptacle, an I/O interface, a memory card interface, etc.

In some embodiments, the image capture apparatus 200 may include features or components other than those described herein, some features or components described herein may be omitted, or some features or components described herein may be combined. For example, the image capture apparatus 200 may include additional interfaces or different interface features, interchangeable lenses, cold shoes, or hot shoes.

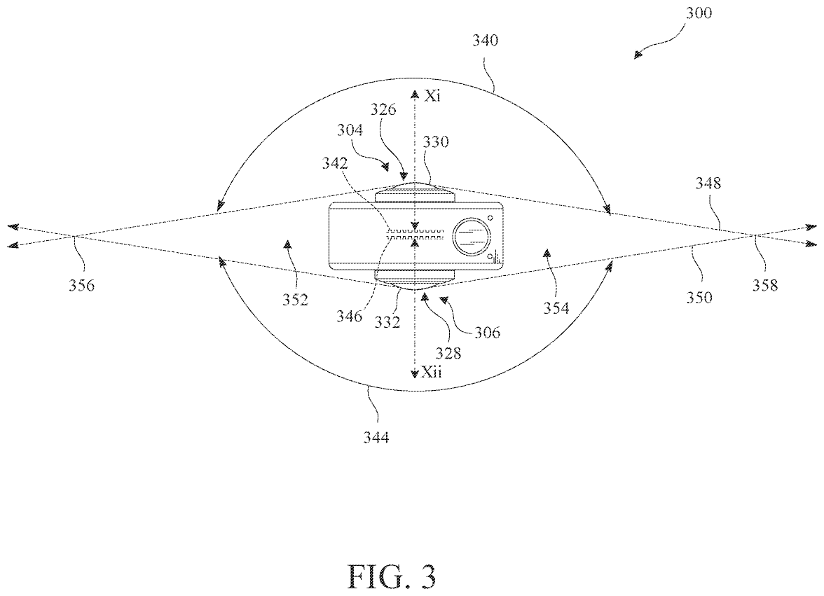

FIG. 3 is a top view of an image capture apparatus 300. The image capture apparatus 300 is similar to the image capture apparatus 200 of FIGS. 2A-2B and is configured to capture spherical images.

As shown in FIG. 3, a first image capture device 304 includes a first lens 330 and a second image capture device 306 includes a second lens 332. For example, the first image capture device 304 may capture a first image, such as a first hemispheric, or hyper-hemispherical, image, the second image capture device 306 may capture a second image, such as a second hemispheric, or hyper-hemispherical, image, and the image capture apparatus 300 may generate a spherical image incorporating or combining the first image and the second image, which may be captured concurrently, or substantially concurrently.

The first image capture device 304 defines a first field-of-view 340 wherein the first lens 330 of the first image capture device 304 receives light. The first lens 330 directs the received light corresponding to the first field-of-view 340 onto a first image sensor 342 of the first image capture device 304. For example, the first image capture device 304 may include a first lens barrel (not expressly shown), extending from the first lens 330 to the first image sensor 342. In the illustrated embodiment, the first lens 330 and the first image sensor 342 are integrated into a single unit, whereby the first image capture device 304 is configured as a first ISLA 326 that defines a first optical axis Xi.

The second image capture device 306 defines a second field-of-view 344 wherein the second lens 332 receives light. The second lens 332 directs the received light corresponding to the second field-of-view 344 onto a second image sensor 346 of the second image capture device 306. For example, the second image capture device 306 may include a second lens barrel (not expressly shown), extending from the second lens 332 to the second image sensor 346. In the illustrated embodiment, the second lens 332 and the second image sensor 346 are integrated into a single unit, whereby the second image capture device 306 is configured as a second ISLA 328 that defines a second optical axis Xii.

A boundary 348 of the first field-of-view 340 is shown using broken directional lines. A boundary 350 of the second field-of-view 344 is shown using broken directional lines. As shown, the image capture devices 304, 306 are arranged in a back-to-back (Janus) configuration such that the lenses 330, 332 face in opposite directions (i.e., a forward direction and a rearward direction), and such that the image capture apparatus 300 may capture spherical images. The first image sensor 342 captures a first hyper-hemispherical image plane from light entering the first lens 330. The second image sensor 346 captures a second hyper-hemispherical image plane from light entering the second lens 332.

As shown in FIG. 3, the fields-of-view 340, 344 partially overlap such that the combination of the fields-of-view 340, 344 forms a spherical field-of-view, except that one or more uncaptured areas 352, 354 may be outside of the fields-of-view 340, 344 of the lenses 330, 332. Light emanating from or passing through the uncaptured areas 352, 354, which may be proximal to the image capture apparatus 300, may be obscured from the lenses 330, 332 and the corresponding image sensors 342, 346, such that content corresponding to the uncaptured areas 352, 354 may be omitted from images captured by the image capture apparatus 300. In some implementations, the image capture devices 304, 306, or the lenses 330, 332 thereof, may be configured to minimize the uncaptured areas 352, 354.

Examples of points of transition, or overlap points, from the uncaptured areas 352, 354 to the overlapping portions of the fields-of-view 340, 344 are shown at overlap points 356, 358.

Images contemporaneously captured by the respective image sensors 342, 346 may be combined to form a combined image, such as a spherical image. Generating a combined image may include correlating the overlapping regions captured by the respective image sensors 342, 346, aligning the captured fields-of-view 340, 344, and stitching the images together to form a cohesive combined image. Stitching the images together may include correlating the overlap points 356, 358 with respective locations in corresponding images captured by the image sensors 342, 346. Although a planar view of the fields-of-view 340, 344 is shown in FIG. 3, the fields-of-view 340, 344 are hyper-hemispherical.

A change in the alignment, such as position, tilt, or a combination thereof, of the image capture devices 304, 306, such as of the lenses 330, 332, the image sensors 342, 346, or both, may change the relative positions of the respective fields-of-view 340, 344, may change the locations of the overlap points 356, 358, such as with respect to images captured by the image sensors 342, 346, and may change the uncaptured areas 352, 354, which may include changing the uncaptured areas 352, 354 unequally.

Incomplete or inaccurate information indicating the alignment of the image capture devices 304, 306, such as the locations of the overlap points 356, 358, may decrease the accuracy, efficiency, or both of generating a combined image. In some implementations, the image capture apparatus 300 may maintain information indicating the location and orientation of the image capture devices 304, 306, such as of the lenses 330, 332, the image sensors 342, 346, or both, such that the fields-of-view 340, 344, the overlap points 356, 358, or both may be accurately determined, which may improve the accuracy, efficiency, or both of generating a combined image.

The ISLAs 326, 328 (e.g., the lenses 330, 332) may be aligned as shown (e.g., such that the optical axes Xi, Xii are coincident with each other), laterally offset from each other (not shown), off-center from a central axis of the image capture apparatus 300 (not shown), or laterally offset and off-center from the central axis (not shown). Whether through use of offset or through use of compact image capture devices 304, 306, a reduction in distance between the lenses 330, 332 may improve the overlap in the fields-of-view 340, 344, such as by reducing the uncaptured areas 352, 354.

Images or frames captured by the image capture devices 304, 306 may be combined, merged, or stitched together to produce a combined image, such as a spherical or panoramic image, which may be an equirectangular planar image. In some implementations, generating a combined image may include use of techniques such as noise reduction, tone mapping, white balancing, or other image correction. In some implementations, pixels along a stitch boundary, which may correspond with the overlap points 356, 358, may be matched accurately to minimize boundary discontinuities.

FIG. 4 is a block diagram of electronic components in an image capture apparatus 400. The image capture apparatus 400 may be a single-lens image capture device, a multi-lens image capture device, or variations thereof, including an image capture apparatus with multiple capabilities such as the use of interchangeable integrated sensor lens assemblies. Components, such as electronic components, of the image capture apparatus 100 shown in FIGS. 1A-1B, the image capture apparatus 200 shown in FIGS. 2A-2B, or the image capture apparatus 300 shown in FIG. 3, may be implemented as shown in FIG. 4.

The image capture apparatus 400 includes a body 402. The body 402 may be similar to the body 102 shown in FIGS. 1A-1B or the body 202 shown in FIGS. 2A-2B. The body 402 includes electronic components such as capture components 410, processing components 420, data interface components 430, spatial sensors 440, power components 450, user interface components 460, and a bus 480.

The capture components 410 include an image sensor 412 for capturing images. Although one image sensor 412 is shown in FIG. 4, the capture components 410 may include multiple image sensors. The image sensor 412 may be similar to the image sensors 342, 346 shown in FIG. 3. The image sensor 412 may be, for example, a charge-coupled device (CCD) sensor, an active pixel sensor (APS), a complementary metal-oxide-semiconductor (CMOS) sensor, or an N-type metal-oxide-semiconductor (NMOS) sensor. The image sensor 412 detects light, such as within a defined spectrum, such as the visible light spectrum or the infrared spectrum, incident through a corresponding lens such as the first lens 330 with respect to the first image sensor 342 or the second lens 332 with respect to the second image sensor 346 as shown in FIG. 3. The image sensor 412 captures detected light as image data and conveys the captured image data as electrical signals (image signals or image data) to the other components of the image capture apparatus 400, such as to the processing components 420, such as via the bus 480.

The capture components 410 include a microphone 414 for capturing audio. Although one microphone 414 is shown in FIG. 4, the capture components 410 may include multiple microphones. The microphone 414 detects and captures, or records, sound, such as sound waves incident upon the microphone 414. The microphone 414 may detect, capture, or record sound in conjunction with capturing images by the image sensor 412. The microphone 414 may detect sound to receive audible commands to control the image capture apparatus 400. The microphone 414 may be similar to the microphones 128, 130, 132 shown in FIGS. 1A-1B or the audio components 218, 220, 222 shown in FIGS. 2A-2B.

The processing components 420 perform image signal processing, such as filtering, tone mapping, or stitching, to generate, or obtain, processed images, or processed image data, based on image data obtained from the image sensor 412. The processing components 420 may include one or more processors having single or multiple processing cores. In some implementations, the processing components 420 may include, or may be, an application specific integrated circuit (ASIC) or a digital signal processor (DSP). For example, the processing components 420 may include a custom image signal processor. The processing components 420 conveys data, such as processed image data, with other components of the image capture apparatus 400 via the bus 480. In some implementations, the processing components 420 may include an encoder, such as an image or video encoder that may encode, decode, or both, the image data, such as for compression coding, transcoding, or a combination thereof.

Although not shown expressly in FIG. 4, the processing components 420 may include memory, such as a random-access memory (RAM) device, which may be non-transitory computer-readable memory. The memory of the processing components 420 may include executable instructions and data that can be accessed by the processing components 420.

The data interface components 430 communicates with other, such as external, electronic devices, such as a remote control, a smartphone, a tablet computer, a laptop computer, a desktop computer, or an external computer storage device. For example, the data interface components 430 may receive commands to operate the image capture apparatus 400. In another example, the data interface components 430 may transmit image data to transfer the image data to other electronic devices. The data interface components 430 may be configured for wired communication, wireless communication, or both. As shown, the data interface components 430 include an I/O interface 432, a wireless data interface 434, and a storage interface 436. In some implementations, one or more of the I/O interface 432, the wireless data interface 434, or the storage interface 436 may be omitted or combined.

The I/O interface 432 may send, receive, or both, wired electronic communications signals. For example, the I/O interface 432 may be a universal serial bus (USB) interface, such as USB type-C interface, a high-definition multimedia interface (HDMI), a FireWire interface, a digital video interface link, a display port interface link, a Video Electronics Standards Associated (VESA) digital display interface link, an Ethernet link, or a Thunderbolt link. Although one I/O interface 432 is shown in FIG. 4, the data interface components 430 include multiple I/O interfaces. The I/O interface 432 may be similar to the data interface 124 shown in FIG. 1B

The wireless data interface 434 may send, receive, or both, wireless electronic communications signals. The wireless data interface 434 may be a Bluetooth interface, a ZigBee interface, a Wi-Fi interface, an infrared link, a cellular link, a near field communications (NFC) link, or an Advanced Network Technology interoperability (ANT+) link. Although one wireless data interface 434 is shown in FIG. 4, the data interface components 430 include multiple wireless data interfaces. The wireless data interface 434 may be similar to the data interface 124 shown in FIG. 1B.

The storage interface 436 may include a memory card connector, such as a memory card receptacle, configured to receive and operatively couple to a removable storage device, such as a memory card, and to transfer, such as read, write, or both, data between the image capture apparatus 400 and the memory card, such as for storing images, recorded audio, or both captured by the image capture apparatus 400 on the memory card. Although one storage interface 436 is shown in FIG. 4, the data interface components 430 include multiple storage interfaces. The storage interface 436 may be similar to the data interface 124 shown in FIG. 1B.

The spatial, or spatiotemporal, sensors 440 detect the spatial position, movement, or both, of the image capture apparatus 400. As shown in FIG. 4, the spatial sensors 440 include a position sensor 442, an accelerometer 444, and a gyroscope 446. The position sensor 442, which may be a global positioning system (GPS) sensor, may determine a geospatial position of the image capture apparatus 400, which may include obtaining, such as by receiving, temporal data, such as via a GPS signal. The accelerometer 444, which may be a three-axis accelerometer, may measure linear motion, linear acceleration, or both of the image capture apparatus 400. The gyroscope 446, which may be a three-axis gyroscope, may measure rotational motion, such as a rate of rotation, of the image capture apparatus 400. In some implementations, the spatial sensors 440 may include other types of spatial sensors. In some implementations, one or more of the position sensor 442, the accelerometer 444, and the gyroscope 446 may be omitted or combined.

The power components 450 distribute electrical power to the components of the image capture apparatus 400 for operating the image capture apparatus 400. As shown in FIG. 4, the power components 450 include a battery interface 452, a battery 454, and an external power interface 456 (ext. interface) The battery interface 452 (bat. interface) operatively couples to the battery 454, such as via conductive contacts to transfer power from the battery 454 to the other electronic components of the image capture apparatus 400 The battery interface 452 may be similar to the battery receptacle 126 shown in FIG. 1B. The external power interface 456 obtains or receives power from an external source, such as a wall plug or external battery, and distributes the power to the components of the image capture apparatus 400, which may include distributing power to the battery 454 via the battery interface 452 to charge the battery 454. Although one battery interface 452, one battery 454, and one external power interface 456 are shown in FIG. 4, any number of battery interfaces, batteries, and external power interfaces may be used. In some implementations, one or more of the battery interface 452, the battery 454, and the external power interface 456 may be omitted or combined. For example, in some implementations, the external power interface 456 and the I/O interface 432 may be combined

The user interface components 460 receive input, such as user input, from a user of the image capture apparatus 400, output, such as display or present, information to a user, or both receive input and output information, such as in accordance with user interaction with the image capture apparatus 400.

As shown in FIG. 4, the user interface components 460 include visual output components 462 to visually communicate information, such as to present captured images. As shown, the visual output components 462 include an indicator 464 and a display 466. The indicator 464 may be similar to the indicator 106 shown in FIG. 1A or the indicators 208 shown in FIGS. 2A-2B. The display 466 may be similar to the display 108 shown in FIG. 1A, the display 142 shown in FIG. 1B, or the display 224 shown in FIG. 2B. Although the visual output components 462 are shown in FIG. 4 as including one indicator 464, the visual output components 462 may include multiple indicators. Although the visual output components 462 are shown in FIG. 4 as including one display 466, the visual output components 462 may include multiple displays. In some implementations, one or more of the indicators 464 or the display 466 may be omitted or combined.

As shown in FIG. 4, the user interface components 460 include a speaker 468. The speaker 468 may be similar to the speaker 138 shown in FIG. 1B or the audio components 218, 220, 222 shown in FIGS. 2A-2B. Although one speaker 468 is shown in FIG. 4, the user interface components 460 may include multiple speakers. In some implementations, the speaker 468 may be omitted or combined with another component of the image capture apparatus 400, such as the microphone 414.

As shown in FIG. 4, the user interface components 460 include a physical input interface 470. The physical input interface 470 may be similar to the mode buttons 110, 210 shown in FIGS. 1A, 2A or the shutter buttons 112, 212 shown in FIGS. 1A, 2B. Although one physical input interface 470 is shown in FIG. 4, the user interface components 460 may include multiple physical input interfaces. In some implementations, the physical input interface 470 may be omitted or combined with another component of the image capture apparatus 400. The physical input interface 470 may be, for example, a button, a toggle, a switch, a dial, or a slider.

As shown in FIG. 4, the user interface components 460 include a broken line border box labeled “other” to indicate that components of the image capture apparatus 400 other than the components expressly shown as included in the user interface components 460 may be user interface components. For example, the microphone 414 may receive, or capture, and process audio signals to obtain input data, such as user input data corresponding to voice commands. In another example, the image sensor 412 may receive, or capture, and process image data to obtain input data, such as user input data corresponding to visible gesture commands. In another example, one or more of the spatial sensors 440, such as a combination of the accelerometer 444 and the gyroscope 446, may receive, or capture, and process motion data to obtain input data, such as user input data corresponding to motion gesture commands.

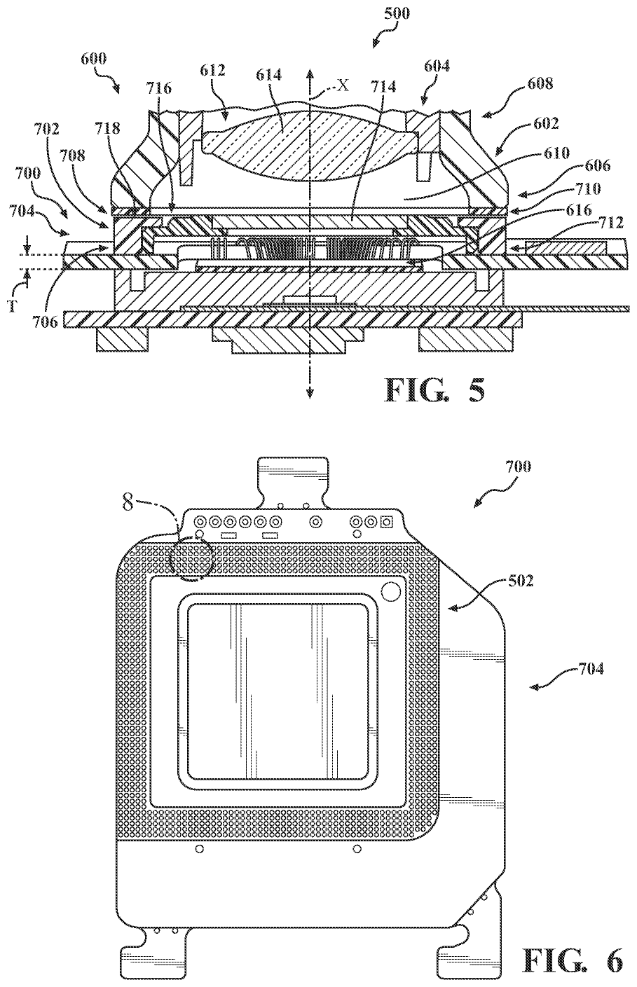

With reference now to FIGS. 5 and 6, an ISLA 500 is illustrated, which defines an optical axis X, and includes a lens assembly 600 and a printed circuit board (PCB) subassembly 700. More specifically, FIG. 5 is a partial, axial, cross-sectional view of the ISLA 500, and FIG. 6 is a partial, plan view of the PCB subassembly 700. The ISLA 500 includes features similar to the aforedescribed ISLAs 326, 328 (FIG. 3), and, accordingly, will only be discussed with respect to differences therefrom in the interest of brevity.

The lens assembly 600 includes a lens holder (mount) 602 and a lens barrel 604.

The lens holder 602 has respective inner and outer ends 606, 608, and defines an internal chamber 610, which extends between the ends 606, 608 thereof. The internal chamber 610 is configured to receive the lens barrel 604 such that the lens barrel 604 protrudes from the outer end 608 of the lens holder 602.

The lens barrel 604 houses (includes, accommodates) an optical group 612 with one or more lenses 614, which include features similar to the aforedescribed lenses 330, 332 (FIG. 3). The lens(es) 614 receive and direct light onto an image sensor 616, which includes features similar to the aforedescribed image sensors 342, 346 (FIG. 3).

The lens barrel 604 is located within, and is connected (secured) to, the lens holder 602 (e.g., concentrically within the internal chamber 610) such that the lens barrel 604 and, thus, the optical group 612 are fixed in relation thereto. For example, it is envisioned that the lens barrel 604 may be adhesively connected (secured) to the lens holder 602 and/or that the lens barrel 604 may be mechanically connected (secured) to the lens holder 602 (e.g., via one or more mechanical fasteners).

The PCB subassembly 700 includes a cover glass holder 702 and a printed circuit board (PCB) 704 that is connected (secured) to the cover glass holder 702 within an optical tolerance loop 502 of the ISLA 500, which generally refers to the area on the PCB 704 corresponding to the footprint of the lens assembly 600.

The cover glass holder 702 has respective inner and outer ends 706, 708, and is connected (secured) to both the lens holder 602 and the PCB 704 (e.g., via an adhesive). More specifically, the cover glass holder 702 is connected (secured) to the lens holder 602 at a (first) interface 710, and the cover glass holder 702 is connected (secured) to the PCB 704 at a (second) interface 712, which is spaced axially from the interface 710 along the optical axis X. The cover glass holder 702 is thus located between, and indirectly connects (secures), the lens holder 602 and the PCB 704 such that the lens holder 602 and the PCB 704 are spaced axially from each other along the optical axis X and are devoid of any direct connection.

The cover glass holder 702 supports a cover glass 714, which protects the image sensor 616 from particles, debris, dust, etc., and acts as an optical filter for the ISLA 500, and includes respective inner and outer modules 716, 718. In the illustrated embodiment, the modules 716, 718 are configured as discrete components that may connected (secured) together in any suitable manner (e.g., via an adhesive, welding, etc.). Embodiments in which the cover glass holder 702 may be unitary (i.e., monolithic) in construction are also envisioned herein, however. For example, an embodiment in which the cover glass holder 702 may be formed via injection molding from a single piece of material would not be beyond the scope of the present disclosure.

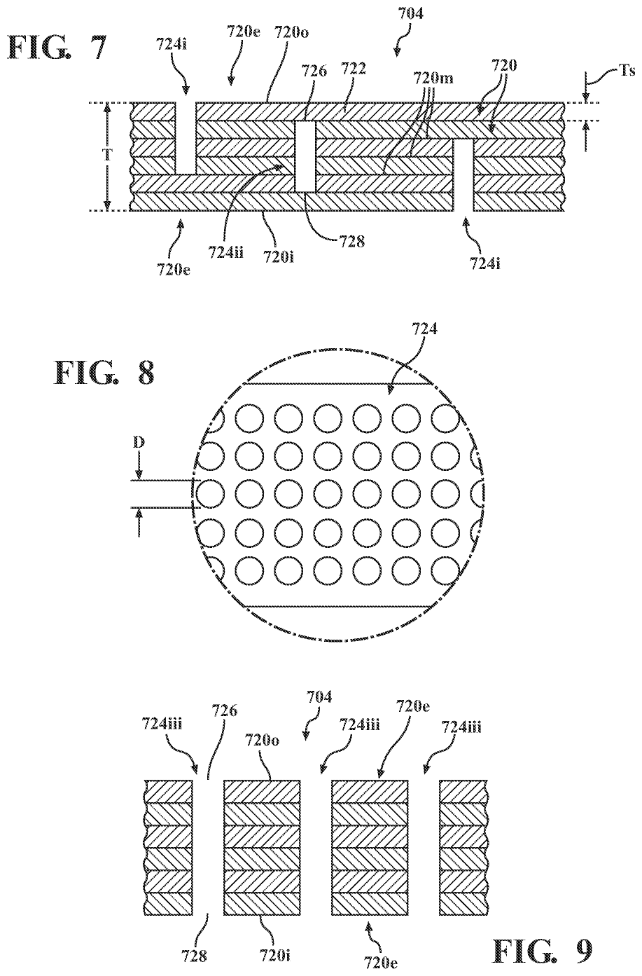

With reference now to FIGS. 7 and 8 as well, the PCB 704 will be discussed. More specifically, FIG. 7 is a partial, cross-sectional view of the PCB 704, and FIG. 8 is an enlargement of the area of detail identified in FIG. 6.

The PCB 704 supports (i.e., is connected (secured) to) the image sensor 616 and is laminated in construction. More specifically, the PCB 704 includes layers of substrate 720 that are positioned in adjacent relation, and which are connected (secured) together so as to define an overall thickness T of the PCB 704. In the illustrated embodiment, the PCB 704 includes approximately 4 layers of substrate to approximately 8 layers of substrate 720, which reduces the thickness T of the PCB 704, and thereby constrains (i.e., inhibits, if not entirely prevents) expansion of the PCB 704 along the optical axis X that might otherwise occur due to fluctuations in temperature and/or humidity (e.g., moisture content), whereby the overall thickness T of the PCB 704 remains generally constant (and/or uniform). Constraining expansion of the PCB 704 inhibits (if not entirely prevents) the misalignment and/or movement of components that might otherwise occur and allows the PCB 704 to remain within acceptable manufacturing tolerances, thereby maintaining optical focus alignment of the ISLA 500, and allowing for the use of high-performance lenses 614 (e.g., lenses with larger apertures, lenes with lower F numbers, etc.). Embodiments in which the number of layers of substrate 720 may lie outside of the disclosed range are also envisioned herein, however, (e.g., depending upon the specific manufacturing tolerances for the PCB 704, desired performance of the ISLA 500, etc.), and would not be beyond the scope of the present disclosure.

In the illustrated embodiment, the PCB 704 is configured such that each layer of substrate 720 defines a generally equivalent thickness Ts that lies substantially within the range of approximately ½ mm to approximately 1 mm. Embodiments in which the thickness Ts may lie outside of the disclosed range are also envisioned herein, however, as are embodiments in which the thickness Ts of the layers of substrate 720 may be non-uniform. For example, an embodiment in which the PCB 704 includes one or more layers of substrate 720 having a different thickness Ts would not be beyond the scope of the present disclosure.

In order to further constrain expansion of the PCB 704, the layers of substrate 720 include (one or more) at least one material 722 with a coefficient of thermal expansion (CTE) that lies substantially within the range of approximately 2 ppm/° C. to approximately 40 ppm/° C., and a coefficient of hygroscopic expansion (CHE) that lies substantially within the range of approximately 2 ppm/100% Hu absorption to approximately 20 ppm/100% Hu absorption. Embodiments in which the material(s) 722 may have a CTE and/or a CHE that lies outside of the disclosed range are also envisioned herein, however, (e.g., depending upon the specific manufacturing tolerances for the PCB 704, desired performance of the ISLA 500, etc.), and would not be beyond the scope of the present disclosure.

With reference to FIGS. 6-8 in particular, the PCB 704 includes vias 724 that are configured to facilitate electrical and/or thermal communication (i.e., the communication of data, power, and/or heat) between the layers of substrate 720 (FIG. 7). The vias 724 are located within the optical tolerance loop 502 of the ISLA 500, and each define a reduced transverse cross-sectional dimension D (e.g., a diameter), when compared to the vias 724 in known PCBs and ISLAs. Reducing the transverse cross-sectional dimension D allows the number of vias 724 in the optical tolerance loop 502 to be increased, which further constrains expansion of the PCB 704 by mechanically locking together the layers of substrate 720, and allows the PCB 704 to remain within acceptable manufacturing tolerances during temperature and/or humidity fluctuations.

In the illustrated embodiment, the vias 724 are include (e.g., are filled with) copper, which further reduces the overall CTE and/or CHE of the PCB 704. Embodiments in which vias 724 may include one or more alternate or additional materials are also envisioned herein, however, and would not be beyond the scope of the present disclosure.

In the illustrated embodiment, the PCB 704 is configured such that the transverse cross-sectional dimension D of each via 724 is generally equivalent and lies substantially within the range of approximately 0.025 mm to approximately 0.5 mm (e.g., approximately 0.1 mm). Embodiments in which the transverse cross-sectional dimension D may lie outside of the disclosed range are also envisioned herein, however, as are embodiments in which the transverse cross-sectional dimension D of the vias 724 may be non-uniform. For example, an embodiment in which the PCB 704 may include vias 724 with varying transverse cross-sectional dimensions D would not be beyond the scope of the present disclosure.

While the vias 724 are shown as being distributed in a generally uniform manner, embodiments of the PCB 704 in which the distribution of the vias 724 may be non-uniform are also envisioned herein. For example, an embodiment of the PCB 704 in which the number of vias 724 may be increased in areas of connection to the image sensor 616 and/or the cover glass holder 702 would not be beyond the scope of the present disclosure.

In the illustrated embodiment, the PCB 704 is configured such that the vias 724 extend partially through the PCB 704 More specifically, the PCB 704 includes (first, blind) vias 724i, which extend inwardly from exterior layers of substrate 720e (i.e., outermost and innermost layers of substrate 720o, 720i, respectively) into intermediate (middle) layers of substrate 720m, which are located between the exterior layers of substrate 720e, and (second, buried) vias 724ii, which include opposite ends 726, 728 that are spaced inwardly from, and are positioned between, the exterior layers of substrate 720e. Although the PCB 704 is shown as including the vias 724i and the vias 724ii in the embodiment illustrated in FIG. 7, embodiments in which the PCB 704 may exclusively include the vias 724i or vias 724ii are also envisioned herein.

FIG. 9 is a partial, cross-sectional view of an alternate embodiment of the PCB 704, which includes vias 724iii that extend entirely therethrough. More specifically, the vias 724iii are configured such that the opposite ends 726, 728 thereof are located within the exterior layers of substrate 720e (i.e., such that the end 726 is located within the outermost layer of substrate 720o, and the end 728 is located within the innermost layer of substrate 720i). In certain embodiments, it is envisioned that the vias 724iii may supplement or replace the vias 724i and/or the vias 724ii. As such embodiment of the PCB 704 are envisioned that include the vias 724i, the vias 724ii, and/or the vias 724iii, either exclusively or in combination.

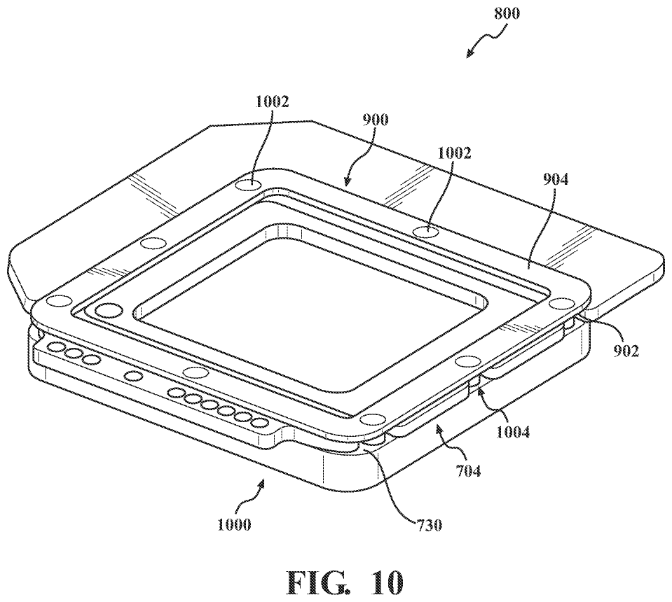

With reference now to FIG. 10, an alternate embodiment of the ISLA 500 will be discussed, which is identified by the reference character 800. More specifically, FIG. 10 is a partial, perspective view of the ISLA 800. The ISLA 800 includes features similar to the aforedescribed ISLA 500 (FIG. 5), and, accordingly, will only be discussed with respect to differences therefrom in the interest of brevity.

In addition to the lens assembly 600 (i.e., the lens holder 602 and the lens barrel 604) and the PCB subassembly 700 (i.e., the cover glass holder 702 and the PCB 704), the ISLA 800 includes a mounting plate 900 and a base plate 1000 (in the interest of clarity, the lens holder 602, the lens barrel 604, and the cover glass holder 702 have been omitted from FIG. 10).

The mounting plate 900 has respective inner and outer ends 902, 904, and is connected (secured) to both the base plate 1000 and the cover glass holder 702. More specifically, in the illustrated embodiment, the outer end 904 of the mounting plate 900 is adhesively connected (secured) to the cover glass holder 702 at the interface 712 (FIG. 5). It should be appreciated, however, that the mounting plate 900 and the cover glass holder 702 may be connected (secured) together in any suitable manner (e.g., via welding, via one or more mechanical fasteners, etc.).

The mounting plate 900 and the base plate 1000 are connected (secured) via standoffs (posts) 1002 that extend therebetween and through the PCB 704. More specifically, in the illustrated embodiment, the PCB 704 includes recesses 730, each of which defines a generally C-shaped configuration that partially circumscribes a corresponding standoff 1002. Embodiments in which the recesses 730 may be replaced by apertures (openings, bosses) defining a generally annular configuration (i.e., such that each aperture entirely circumscribes a corresponding standoff 1002) are also envisioned herein, however, and would not be beyond the scope of the present disclosure.

The standoffs 1002 separate the mounting plate 900 and the base plate 1000, and thereby define a receiving space 1004 that is configured to receive the PCB 704 such that the PCB 704 is positioned within the receiving space 1004 upon assembly of the ISLA 800. Thus, in contrast to the ISLA 500 (FIG. 5), in which the PCB 704 is directly connected (secured) to the cover glass holder 702, in the ISLA 800, the PCB 704 is indirectly connected (secured) to the cover glass holder 702 via the mounting plate 900.

In various embodiments of the disclosure, it is envisioned that the PCB 704 may be fixedly connected (secured) to the mounting plate 900 and/or to the base plate 1000. For example, it is envisioned that the PCB 704 may be connected (secured) to the mounting plate 900 and/or to the base plate 1000 via an adhesive, via welding, via one or more mechanical fasteners, etc.).

In addition to connecting (securing) and separating the mounting plate 900 and the base plate 1000, the standoffs 1002 mechanically lock the mounting plate 900 and the base plate 1000 in relation to each other so as to inhibit (if not entirely prevent) relative movement therebetween (i.e., along the optical axis X (FIG. 5)). The standoffs 1002 thus generally fix the configuration of the receiving space 1004, whereby the mounting plate 900 and the base plate 1000 collectively constrain expansion of the PCB 704 so as to maintain optical focus alignment of the ISLA 800 in the manner discussed above.

In the illustrated embodiment, the standoffs 1002 are formed integrally (i.e., monolithically, unitarily) with the base plate 1000, whereby the base plate 1000 and the standoffs 1002 are formed from a single piece of material and are connected (secured) to the mounting plate 900 (e.g., via welding). Embodiments in which the base plate 1000, the standoffs 1002, and/or the mounting plate 900 may be configured as discrete (separate) components of the ISLA 800 are also envisioned herein, however, and would not be beyond the scope of the present disclosure.

Although shown as including eight standoffs 1002 in the illustrated embodiment, it is envisioned that the number of standoffs 1002 may be increased or decreased without departing from the scope of the present disclosure.

With reference now to FIGS. 5-10, methods of assembling the ISLA 500 (FIG. 5) and the ISLA 800 (FIG. 10) will be discussed.

In any suitable sequence of assembly, the methods include: connecting (securing) the lens barrel 604 (and the optical group 612) to the lens holder 602 such that the lens barrel 604 is located concentrically within the internal chamber 610 (FIG. 5)); connecting (securing) the image sensor 616 to the PCB 704; connecting (securing) the cover glass holder 702 to the lens holder 602; connecting (securing) the PCB 704 to the cover glass holder 702; and constraining expansion of the PCB 704 along the optical axis X.

In the context of the ISLA 500 (FIG. 5), connecting (securing) the PCB 704 to the cover glass holder 702 includes directly connecting (securing) the PCB 704 to the cover glass holder 702, and constraining expansion of the PCB 704 includes forming the PCB 704 from the material(s) 722 (FIG. 7); the material(s) 722 include a CTE and CHE that inhibit (if not entirely prevent) deformation of the PCB 704 in the manner discussed above so as to maintain focus alignment of the ISLA 500 despite fluctuations in temperature and/or humidity.

Additionally, it is envisioned that constraining expansion of the PCB 704 may include forming the PCB 704 so as to include the aforementioned laminated construction (e.g., with approximately 4 layers of substrate to approximately 8 layers of substrate 720 (FIG. 7), wherein the thickness Ts of each layer of substrate 720 is generally equivalent and lies substantially within the range of approximately ½ mm to approximately 1 mm).

In context of the ISLA 800 (FIG. 10), connecting (securing) the PCB 704 to the cover glass holder 702 includes indirectly connecting (securing) the PCB 704 to the cover glass holder 702 (i.e., via the mounting plate 900), and constraining expansion of the PCB 704 includes interposing the PCB 704 between the mounting plate 900 and the base plate 1000. Additionally, assembly of the ISLA 800 includes connecting (securing) the mounting plate 900 to the base plate 1000 via the standoffs 1002 so as to define the receiving space 1004 (e.g., via welding of the standoffs 1002 to the mounting plate 900) that receives the PCB 704, and assembly of the ISLA 800 also includes connecting (securing) the mounting plate 900 to the cover glass holder 702 such that the mounting plate 900 separates the PCB 704 from the cover glass holder 702.

While the present disclosure has been described in connection with certain embodiments, it is to be understood that the present disclosure is not to be limited to the disclosed embodiments, but, on the contrary, is intended to cover various modifications and equivalent arrangements included within the scope of the appended claims, which scope is to be accorded the broadest interpretation so as to encompass all such modifications and equivalent structures as is permitted under the law.

Persons skilled in the art will understand that the various embodiments of the present disclosure and shown in the accompanying figures constitute non-limiting examples, and that additional components and features may be added to any of the embodiments discussed hereinabove without departing from the scope of the present disclosure. Additionally, persons skilled in the art will understand that the elements and features shown or described in connection with one embodiment may be combined with those of another embodiment without departing from the scope of the present disclosure to achieve any desired result and will appreciate further features and advantages of the presently disclosed subject matter based on the description provided. Variations, combinations, and/or modifications to any of the embodiments and/or features of the embodiments described herein that are within the abilities of a person having ordinary skill in the art are also within the scope of the present disclosure, as are alternative embodiments that may result from combining, integrating, and/or omitting features from any of the disclosed embodiments.

Use of the term “optionally” with respect to any element of a claim means that the element may be included or omitted, with both alternatives being within the scope of the claim Additionally, use of broader terms such as “comprises,” “includes,” and “having” should be understood to provide support for narrower terms such as “consisting of,” “consisting essentially of,” and “comprised substantially of.” Accordingly, the scope of protection is not limited by the description set out above, but is defined by the claims that follow, and includes all equivalents of the subject matter of the claims.

In the preceding description, reference may be made to the spatial relationship between the various structures illustrated in the accompanying drawings, and to the spatial orientation of the structures. However, as will be recognized by those skilled in the art after a complete reading of this disclosure, the structures described herein may be positioned and oriented in any manner suitable for their intended purpose. Thus, the use of terms such as “above,” “below,” “upper,” “lower,” “inner,” “outer,” “left,” “right,” “upward,” “downward,” “inward,” “outward,” “horizontal,” “vertical,” etc., should be understood to describe a relative relationship between the structures and/or a spatial orientation of the structures. Those skilled in the art will also recognize that the use of such terms may be provided in the context of the illustrations provided by the corresponding figure(s).

Additionally, terms such as “generally,” “approximately,” “substantially,” and the like should be understood to include the numerical range, concept, or base term with which they are associated as well as variations in the numerical range, concept, or base term on the order of up to 25% (e.g., to allow for manufacturing tolerances and/or deviations in design). For example, the term “generally parallel” should be understood as referring to an arrangement in which the pertinent components (structures, elements) subtend an angle therebetween that is equal to 180° as well as an arrangement in which the pertinent components (structures, elements) subtend an angle therebetween that is greater than or less than 180° (e.g., ±10%, ±15%, ±25%). The term “generally parallel” should thus be understood as encompassing configurations in which the pertinent components are arranged in parallel relation. Similarly, the term “generally identical” should be understood as encompassing configurations in which the pertinent components are identical in configuration as well as configurations in which there may be insubstantial variations between the pertinent components that do not influence the substantive construction or performance thereof.

Although terms such as “first,” “second,” “third,” etc., may be used herein to describe various operations, elements, components, regions, and/or sections, these operations, elements, components, regions, and/or sections should not be limited by the use of these terms in that these terms are used to distinguish one operation, element, component, region, or section from another. Thus, unless expressly stated otherwise, a first operation, element, component, region, or section could be termed a second operation, element, component, region, or section without departing from the scope of the present disclosure, etc.

Each and every claim is incorporated as further disclosure into the specification and represents embodiments of the present disclosure. Also, the phrases “at least one of A, B, and C” and “A and/or B and/or C” should each be interpreted to include only A, only B, only C, or any combination of A, B, and C.

What is claimed is:

1. An integrated sensor-lens assembly (ISLA) for an image capture apparatus, the ISLA comprising:
a lens holder;
a cover glass holder connected to the lens holder;
a printed circuit board (PCB) connected to the cover glass holder within an optical tolerance loop of the ISLA, wherein the PCB includes at least one material having a coefficient of thermal expansion that lies substantially within a range of approximately 2 ppm/° C. to approximately 40 ppm/° C. and a coefficient of hygroscopic expansion that lies substantially within a range of approximately 2 ppm/100% Hu absorption to approximately 20 ppm/100% Hu absorption; and
an image sensor connected to the PCB.

2. The ISLA of claim 1, wherein the PCB is laminated in construction, and includes approximately 4 layers of substrate to approximately 8 layers of substrate.

3. The ISLA of claim 2, wherein each layer of substrate defines a generally equivalent thickness.

4. The ISLA of claim 3, wherein each layer of substrate defines a thickness that lies substantially within a range of approximately ½ mm to approximately 1 mm.

5. The ISLA of claim 2, wherein the PCB includes vias located within the optical tolerance loop, wherein the vias are configured to facilitate electrical and/or thermal communication between the layers of substrate, and wherein each via defines a transverse cross-sectional dimension that lies substantially within a range of approximately 0.025 mm to approximately 0.5 mm.

6. An integrated sensor-lens assembly (ISLA) for an image capture apparatus, the ISLA defining an optical axis and comprising:
a lens holder;
a cover glass holder connected to the lens holder;
a mounting plate connected to the cover glass holder;
a base plate connected to the mounting plate via standoffs extending therebetween so as to define a receiving space;
a printed circuit board (PCB) positioned within the receiving space such that the PCB is indirectly connected to the cover glass holder via the mounting plate, wherein the mounting plate and the base plate cooperate to constrain expansion of the PCB along the optical axis so as to maintain focus alignment of the ISLA; and
an image sensor connected to the PCB.

7. The ISLA of claim 6, wherein the standoffs extend through the PCB.

8. The ISLA of claim 6, wherein the PCB is laminated in construction and includes:
layers of substrate positioned in adjacent relation; and
vias positioned within an optical tolerance loop of the ISLA, wherein the vias extend through the layers of substrate to facilitate electrical and/or thermal communication therebetween.

9. The ISLA of claim 8, wherein the vias extend partially through the PCB.

10. The ISLA of claim 8, wherein the PCB includes:
first vias extending inwardly from an exterior layer of substrate into intermediate layers of substrate; and
second vias including opposite ends spaced inwardly from the exterior layer of substrate.

11. A method of assembling an integrated sensor-lens assembly (ISLA), the method comprising:
connecting a lens holder to a cover glass holder;
connecting an image sensor to a printed circuit board (PCB);
connecting the PCB to the cover glass holder; and
constraining expansion of the PCB along an optical axis of the ISLA so as to maintain focus alignment of the ISLA.

12. The method of claim 11, wherein connecting the PCB to the cover glass holder includes directly connecting the PCB to the cover glass holder.

13. The method of claim 12, wherein constraining expansion of the PCB includes forming the PCB from at least one material having a coefficient of thermal expansion that lies substantially within a range of approximately 2 ppm/° C. to approximately 40 ppm/° C. and a coefficient of hygroscopic expansion that lies substantially within a range of approximately 2 ppm/100% Hu absorption to approximately 20 ppm/100% Hu absorption.

14. The method of claim 13, wherein forming the PCB includes forming the PCB with a laminated construction that includes approximately 4 layers of substrate to approximately 8 layers of substrate.

15. The method of claim 14, wherein forming the PCB includes forming the PCB such that each layer of substrate defines a generally equivalent thickness.

16. The method of claim 15, wherein forming the PCB includes forming the PCB such that each layer of substrate defines a thickness that lies substantially within a range of approximately ½ mm to approximately 1 mm.

17. The method of claim 11, wherein connecting the PCB to the cover glass holder includes indirectly connecting the PCB to the cover glass holder.

18. The method of claim 17, wherein constraining expansion of the PCB includes interposing the PCB between a mounting plate and a base plate.

19. The method of claim 18, further comprising:
connecting the mounting plate to the base plate via standoffs so as to define a receiving space configured to receive the PCB.

20. The method of claim 19, further comprising:
connecting the mounting plate to the cover glass holder such that the mounting plate separates the PCB from the cover glass holder.
